(19) United States
(12) Patent Application Publication
(10) Pub. No.: US 2026/0231419 A1
(43) Pub. Date: Aug. 6, 2026

(54) SEMICONDUCTOR DEVICE

(71) Applicant: Kioxia Corporation, Tokyo (JP)

(72) Inventor: Yosuke MITSUNO, Yokkaichi (JP)

(73) Assignee: Kioxia Corporation, Tokyo (JP)

(21) Appl. No.: 19/324,462

(22) Filed: Sep. 10, 2025

(30) Foreign Application Priority Data
Feb. 5, 2025 (JP) 2025-017630

(51) Int. Cl. H10B 43/35; H10B 43/10; H10B 43/27

(52) U.S. Cl. CPC H10B 43/35; H10B 43/10; H10B 43/27

(57) ABSTRACT

A semiconductor device includes a substrate and stacked bodies including wiring layers and insulator layers stacked on the substrate in a first direction, and a columnar body extending in a first direction through the stacked bodies. A hole accommodating the columnar body has a portion where an inner diameter changes continuously in the first direction. At least one of a block insulating film, a charge storage film, or a tunnel insulating film provided on the wiring layers and the insulator layers has a film thickness at a position where the hole has a first inner diameter, the film thickness being larger than a film thickness at a position where the inner diameter of the hole is larger than the first inner diameter and being smaller than a film thickness at a position where the inner diameter of the hole is smaller than the first inner diameter.

### CROSS-REFERENCE TO RELATED APPLICATION

This application is based upon and claims the benefit of priority from Japanese Patent Application No. 2025-017630, filed Feb. 5, 2025, the entire contents of which are incorporated herein by reference.

### FIELD

Embodiments described herein relate generally to a semiconductor device.

### BACKGROUND

In recent years, semiconductor devices in which memory cells are integrated three-dimensionally have been proposed. In such semiconductor devices, a through via hole is formed in a stacked body in which insulating layers and conductive layers are alternately stacked, and a memory layer capable of storing charges and a silicon layer are formed on an inner surface of the through via hole, thereby forming a memory cell between the silicon layer and the conductive layer.

### DESCRIPTION OF THE DRAWINGS

FIG. 1 is a block diagram showing an example of a configuration of a memory system according to a first embodiment.

FIG. 2 is a circuit diagram showing an example of a circuit configuration of a memory cell array provided in a semiconductor memory device according to the first embodiment.

FIG. 3 is a perspective view showing an example of the external appearance of the semiconductor memory device according to the first embodiment.

FIG. 4 is a perspective view showing an overview of a bonding structure of the semiconductor memory device according to the first embodiment.

FIG. 5 is a plan view showing an example of a planar layout of the memory cell array provided in the semiconductor memory device according to the first embodiment.

FIG. 6 is a plan view showing an example of a planar layout in a memory cell region of the memory cell array provided in the semiconductor memory device according to the first embodiment.

FIG. 7 is a cross-sectional view taken along line VII-VII in FIG. 6, showing an example of a cross-sectional structure in the memory area of the memory cell array provided in the semiconductor memory device according to the first embodiment.

FIG. 8 is a diagram showing an example of a vertical cross-sectional structure of a columnar body provided in the memory area.

FIG. 9 is a diagram showing an example of a horizontal cross-sectional structure of the columnar body provided in the memory area.

FIG. 10A is a cross-sectional view showing an example of a memory hole formed in the memory cell region.

FIG. 10B is a cross-sectional view showing a state where a block oxide film is formed in the memory hole.

FIG. 10C is a cross-sectional view showing a state where the thickness of the block oxide film is adjusted by slimming.

FIG. 11 is a partially enlarged cross-sectional view showing an example of a cross-sectional structure of a memory hole and a block oxide film in a memory area of a memory system according to a second embodiment.

FIG. 12 is a partially enlarged cross-sectional view showing an example of a cross-sectional structure of a memory hole and a block oxide film in a memory area of a memory system according to a third embodiment.

### DETAILED DESCRIPTION

Embodiments provide a semiconductor device with improved uniformity of a write voltage.

In general, according to one embodiment, a semiconductor device includes a substrate (e.g., W1), a plurality of stacked bodies (e.g., 51, 52, 53), and a columnar body (e.g., MP). The stacked bodies are provided on the substrate, each include a plurality of wiring layers (e.g., 22, 23, 24) and a plurality of insulator layers (e.g., 41-46), and is configured such that the plurality of wiring layers and the plurality of insulator layers are alternately stacked in a first direction (e.g., Z1 direction). The columnar body extends in the first direction through each of the stacked bodies. The columnar body includes a block insulating film (e.g., 35) provided on the plurality of wiring layers and the plurality of insulator layers in a second direction intersecting the first direction (e.g., X, Y, or any direction intersecting Z1 direction). The columnar body includes a charge storage film (e.g., 34) provided on the block insulating film in the second direction. The columnar body includes a tunnel insulating film (e.g., 33) provided on the charge storage film in the second direction. The columnar body includes a semiconductor film (e.g., 31) provided on the tunnel insulating film in the second direction. A hole (e.g., MH1, MH2, MH3) extending in the first direction and accommodating the columnar body is formed in each of the stacked bodies. The hole has a portion where the inner diameter changes continuously in the first direction. An inverse correlation is established in which at least one of the block insulating film, the charge storage film, and the tunnel insulating film has a film thickness that is larger at a position where the inner diameter of the hole is small and that is smaller at a position where the inner diameter of the hole is large, when comparing the film thickness at the position where an inner diameter of the hall is small and at the position where an inner diameter of the hall is large.

A semiconductor device according to each embodiment will be described in detail below with reference to the accompanying drawings. The drawings are schematic, and the dimensions and ratios of the drawings are not necessarily the same as those in reality. Furthermore, the present disclosure is not limited to these embodiments.

In the following description, components having substantially the same functions and configurations are given the same reference numerals. In the following description, a first element being “connected” to a second element includes the first element being indirectly connected to the second element via an intermediate element that is always or selectively conductive, or directly connected to the second element without an intermediate element.

### 1. First Embodiment

A semiconductor device according to a first embodiment will be described below. The semiconductor device is, for example, a non-volatile semiconductor memory device (semiconductor memory) in which a plurality of memory cells are arranged in a three-dimensional direction.

### 1.1 Configuration

### 1.1.1 Memory System

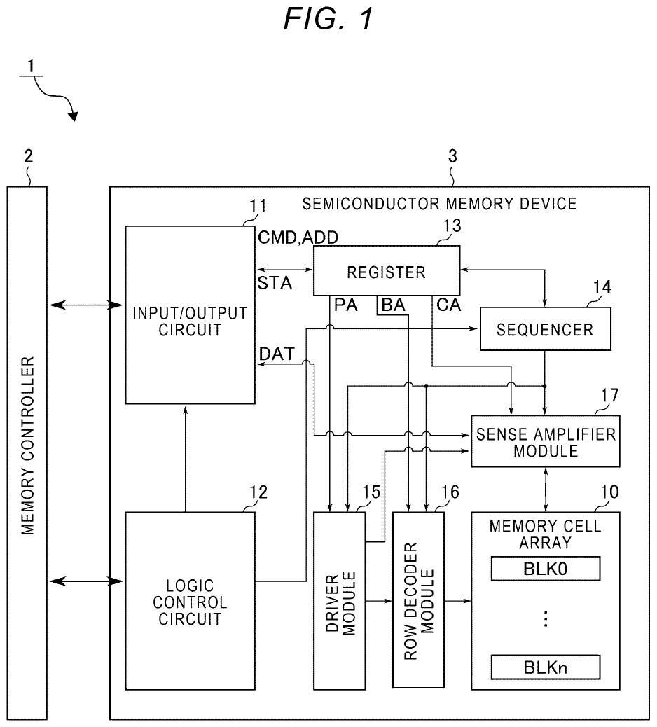

A semiconductor memory device according to the first embodiment will be described. FIG. 1 is a block diagram showing an example of the configuration of a memory system according to the first embodiment. A memory system 1 is a storage device configured to be connected to an external host device (not shown). The memory system 1 is, for example, a memory card such as an SD™ card, a universal flash storage (UFS), or a solid state drive (SSD). The memory system 1 includes a memory controller 2 and a semiconductor memory device 3.

The memory controller 2 is configured with an integrated circuit such as a system on a chip (SoC). The memory controller 2 controls the semiconductor memory device 3 on the basis of a request from the external host device. Specifically, the memory controller 2 writes data requested to be written by the external host device to the semiconductor memory device 3. The memory controller 2 also reads data, which is requested to be read by the external host device, from the semiconductor memory device 3 and outputs it to the external host device.

The semiconductor memory device 3 is, for example, a NAND flash memory capable of storing data in a non-volatile manner.

Communication between the memory controller 2 and the semiconductor memory device 3 is compliant with, for example, a single data rate (SDR) interface, a toggle double data rate (DDR) interface, or an open NAND flash interface (ONFI).

### 1.1.2 Semiconductor Memory Device

Next, an internal configuration of the semiconductor memory device 3 according to the first embodiment will be described with reference to the block diagram shown in FIG. 1. The semiconductor memory device 3 includes, for example, a memory cell array 10, an input/output circuit 11, a logic control circuit 12, a register 13, a sequencer 14, a driver module 15, a row decoder module 16, and a sense amplifier module 17.

The memory cell array 10 is a set of memory cell transistors and a collection of components connected to the memory cell transistors. The memory cell array 10 includes a plurality of blocks BLK0 to BLKn (n is an integer equal to or greater than 1). The block BLK is a collection of a plurality of memory cell transistors capable of storing data in a non-volatile manner. The block BLK is used as, for example, an erase unit when erasing the data stored in the memory cell transistor. The memory cell array 10 is also provided with a plurality of bit lines and a plurality of word lines. Each memory cell transistor is associated with, for example, a combination of one bit line and one word line. A detailed configuration of the memory cell array 10 will be described later.

The input/output circuit 11 is an interface circuit that controls the transmission and reception of input/output signals to and from the memory controller 2. The input/output signals include, for example, data DAT, a command CMD, address information ADD, and status information STA. The input/output circuit 11 inputs and outputs data DAT to and from each of the sense amplifier module 17 and the memory controller 2. The input/output circuit 11 outputs each of the command CMD and the address information ADD, which are transferred from the memory controller 2, to the register 13. The input/output circuit 11 outputs the status information STA, which is transferred from the register 13, to the memory controller 2.

The logic control circuit 12 receives a control signal input from the memory controller 2. The logic control circuit 12 controls each of the input/output circuit 11 and the sequencer 14 on the basis of the control signal. For example, the logic control circuit 12 notifies the input/output circuit 11 that the input/output signal received by the input/output circuit 11 is the command CMD, the address information ADD, or the like. The logic control circuit 12 instructs the input/output circuit 11 to input or output the input/output signal. The logic control circuit 12 controls the sequencer 14 and enables the semiconductor memory device 3. The logic control circuit 12 also outputs a signal indicating whether the semiconductor memory device 3 is in a ready or busy state to the memory controller 2.

The register 13 temporarily stores the command CMD, the address information ADD, and the status information STA. The command CMD includes, for example, an instruction to cause the sequencer 14 to perform a read operation, a write operation, an erase operation, and the like. The address information ADD includes, for example, a block address BA, a page address PA, and a column address CA. For example, the block address BA, the page address PA, and the column address CA are used to select the block BLK, the word line, and the bit line, respectively. The status information STA is updated under the control of the sequencer 14 and transferred to the input/output circuit 11.

The sequencer 14 controls the overall operation of the semiconductor memory device 3. For example, the sequencer 14 controls the driver module 15, the row decoder module 16, and the sense amplifier module 17 on the basis of the command CMD stored in the register 13, and executes a read operation, a write operation, an erase operation, and the like.

The driver module 15 generates a plurality of voltages with different magnitudes that are used in the read operation, the write operation, the erase operation, and the like. The driver module 15 supplies the generated voltages to the row decoder module 16, the sense amplifier module 17, and the like. For example, the driver module 15 also applies the generated voltages to a signal line that corresponds to a word line selected on the basis of the page address PA stored in the register 13.

For example, the row decoder module 16 selects one corresponding block BLK in the memory cell array 10 on the basis of the block address BA stored in the register 13. For example, the row decoder module 16 transfers the voltage of the signal line applied by the driver module 15 to the selected word line in the selected block BLK.

The sense amplifier module 17 includes a sense amplifier capable of determining data on the basis of the voltage of the associated bit line, a latch circuit for temporarily storing data, and the like. In the write operation, the sense amplifier module 17 applies a desired voltage to each bit line in accordance with the write data DAT received from the input/output circuit 11. In the read operation, the sense amplifier module 17 determines the data stored in the memory cell transistor on the basis of the magnitude of the voltage of the bit line. The sense amplifier module 17 then transfers a determination result to the input/output circuit 11 as the read data DAT.

### 1.1.3 Circuit Configuration of Memory Cell Array

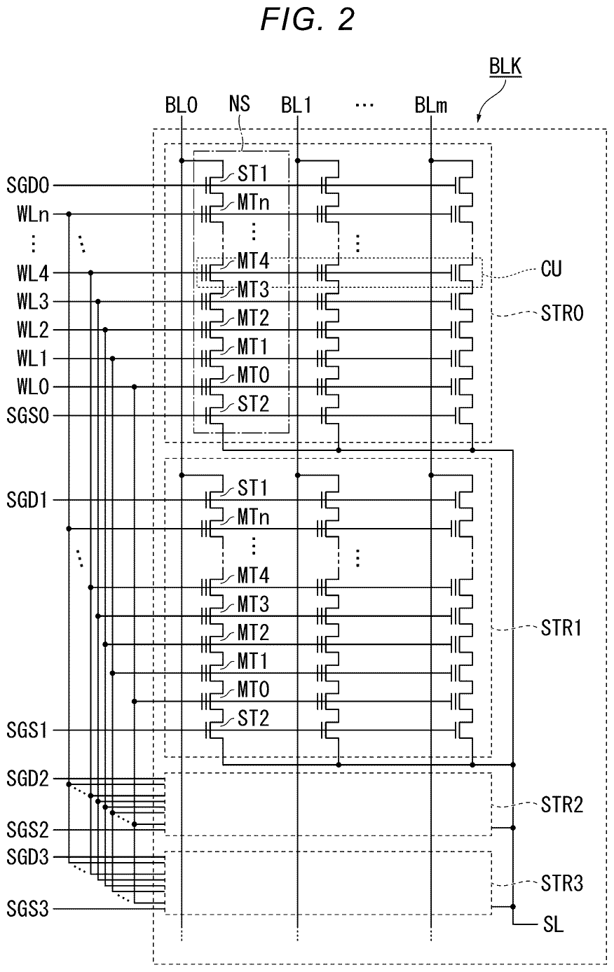

FIG. 2 is a circuit diagram showing an example of a circuit configuration of a memory cell array provided in the semiconductor memory device 3 according to the first embodiment. FIG. 2 shows a block BLK. The block BLK includes, for example, a plurality of string units STR (for example, four STR0 to STR3).

Each string unit STR includes a plurality of NAND strings NS associated with bit lines BL0 to BLm (m is an integer equal to or greater than 1). Each NAND string NS includes memory cell transistors MT0 to MTn, select transistors ST1 and ST2. Each memory cell transistor MT includes a control gate and a charge storage part. The control gate of the memory cell transistor MT is connected to one of the word lines WL0 to WLn. In each memory cell transistor MT, charges are stored in the charge storage part in accordance with a voltage applied to the control gate via the word line WL, and data is stored in a non-volatile manner.

A drain of a drain-side select transistor ST1 is connected to the bit line BL corresponding to the NAND string NS. A source of the drain-side select transistor ST1 is connected to one ends of the memory cell transistors MT0 to MTn connected in series. A control gate of the drain-side select transistor ST1 is connected to one of drain-side select gate lines SGD0 to SGD3. The drain-side select transistor ST1 is electrically connected to the row decoder module 16 via the drain-side select gate line SGD. The drain-side select transistor ST1 connects the NAND string NS to the bit line BL when a predetermined voltage is applied to the corresponding drain-side select gate line SGD.

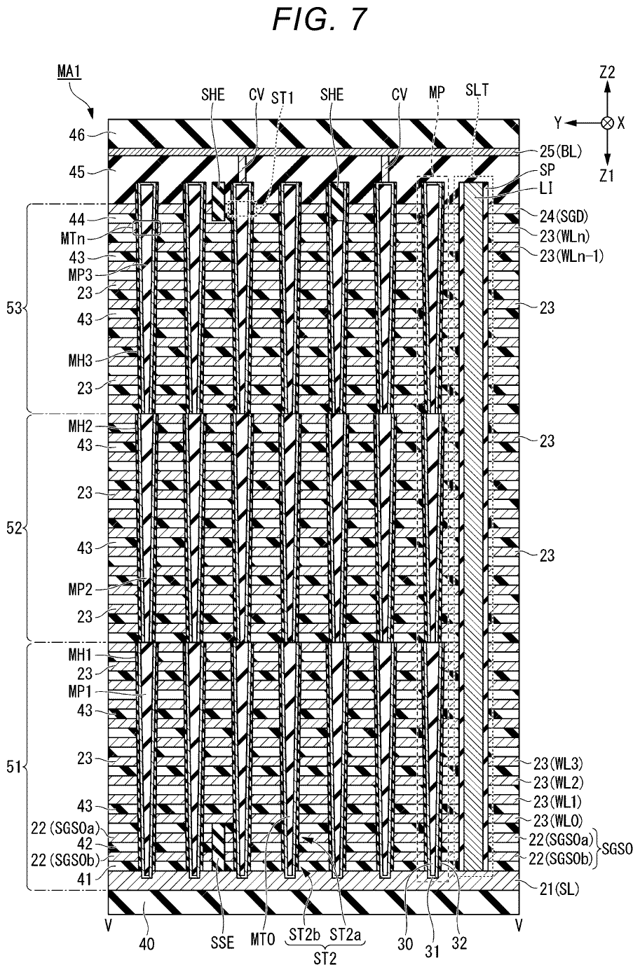

A drain of a source-side select transistor ST2 is connected to the other ends of the memory cell transistors MT0 to MTn connected in series. A source of the source-side select transistor ST2 is connected to a source line SL. A control gate of the source-side select transistor ST2 is connected to one of source-side select gate lines SGS0 to SGS3. The source-side select transistor ST2 connects the NAND string NS to the source line SL when a predetermined voltage is applied to the source-side select gate line SGS. The source-side select gate line SGS0 may be divided by a member SSE as shown in FIG. 7. In this case, the source-side select gate line SGS0 on the left side in FIG. 7 and the source-side select gate line SGS0 on the right side in FIG. 7 may be connected to separate power supplies and may be controlled individually.

In the same block BLK, the control gates of the memory cell transistors MT0 to MTn are connected in common to the corresponding word lines WL0 to WLn. In the same string unit STR, the control gates of the drain-side select transistors ST1 are connected in common to the corresponding drain-side select gate line SGD. The control gates of the source-side select transistors ST2 are connected in common to the corresponding source-side select gate line SGS. In the memory cell array 10, the bit line BL is shared by the NAND strings NS that are assigned the same column address in the plurality of string units STR.

Each of the word lines WL0 to WLn is provided for each block BLK. The source line SL is shared, for example, between the plurality of blocks BLK.

A collection of the plurality of memory cell transistors MT connected to a common word line WL within one string unit STR is referred to as, for example, a cell unit CU. For example, the storage capacity of a cell unit CU that includes memory cell transistors MT each storing 1-bit data is defined as “one page data”. The cell unit CU can have a storage capacity of two or more pieces of page data depending on the number of bits of data stored by the memory cell transistor MT.

A circuit configuration of the memory cell array 10 provided in the semiconductor memory device 3 according to the first embodiment is not limited to the above description. For example, the number of string units STR provided in each block BLK can be designed to be any number. However, it is preferable that the number of string units STR provided in each block BLK is an even number. The number of memory cell transistors MT and the number of select transistors ST1 and ST2 provided in each NAND string NS can be designed to be any number.

### 1.1.4 External Appearance of Semiconductor Memory Device

The semiconductor memory device 3 according to the first embodiment is formed by bonding two semiconductor circuit boards, each having a semiconductor circuit formed thereon, and then separating the bonded semiconductor circuit boards into individual chips. That is, the semiconductor memory device 3 according to the first embodiment includes a structure formed by bonding semiconductor substrates W1 and W2 together. Each of the semiconductor substrates W1 and W2 is, for example, a silicon substrate.

In the following description, a case where the semiconductor substrate W2 is removed during the manufacturing process of the semiconductor memory device 3 will be described. Depending on the structure of the memory cell array 10, a part of the semiconductor substrate W2 may remain after bonding.

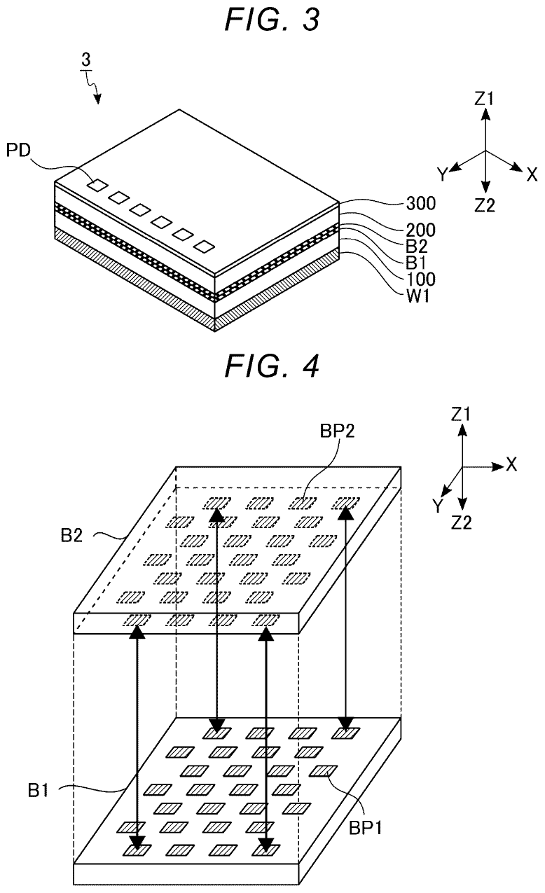

FIG. 3 is a perspective view showing an example of the external appearance of the semiconductor memory device according to the first embodiment. Although hatching is added to improve the visibility of the drawing in FIG. 3, it is not necessarily related to the material or characteristics of a component to which hatching is added. As shown in FIG. 3, the semiconductor memory device 3 has a structure in which, for example, the semiconductor substrate W1, a control circuit layer 100, a bonding layer B1, a bonding layer B2, a memory layer 200, and a wiring layer 300 are stacked in this order.

In the following description, the plane in which the semiconductor substrate W1 extends is an XY plane. Among directions in which a stacked structure is stacked, a direction from the semiconductor substrate W1 toward the wiring layer 300 is set to be a Z1 direction, and a direction from the wiring layer 300 toward the semiconductor substrate W1 is set to be a Z2 direction. The Z1 direction and the Z2 direction are substantially perpendicular to the semiconductor substrate W1. When the Z1 direction and the Z2 direction are not distinguished from each other, each of the Z1 direction and the Z2 direction is simply referred to as a Z direction. The Z direction is also referred to as a first direction.

The control circuit layer 100 includes a control circuit formed using the semiconductor substrate W1. The semiconductor substrate W1 has an impurity diffusion region and the like according to the design of the control circuit. The control circuit layer 100 includes, for example, the input/output circuit 11, the logic control circuit 12, the register 13, the sequencer 14, the driver module 15, the row decoder module 16, and the sense amplifier module 17.

The bonding layer B1 is formed using the semiconductor substrate W1. The bonding layer B1 includes a plurality of bonding pads that are electrically connected to the control circuit provided in the control circuit layer 100 and form a part of the semiconductor circuit.

The bonding layer B2 is formed using the semiconductor substrate W2 (not shown). The bonding layer B2 includes a plurality of bonding pads that are electrically connected to the memory cell array 10 provided in the memory layer 200 and form a part of the semiconductor circuit.

The memory layer 200 includes the memory cell array 10 formed using the semiconductor substrate W2 (not shown).

The wiring layer 300 is formed after bonding the semiconductor substrates W1 and W2 together. The wiring layer 300 includes a wiring connected to the semiconductor circuit provided in the memory layer 200 and a plurality of pads PD. The plurality of pads PD are exposed on the surface of the semiconductor memory device 3. The plurality of pads PD are used to connect the semiconductor memory device 3, the memory controller 2, and the like.

FIG. 4 is a perspective view showing an overview of a bonding structure of the semiconductor memory device according to the first embodiment. The bonding of the semiconductor substrates W1 and W2 will be described using FIG. 4.

As shown in FIG. 4, a plurality of bonding pads BP1 in the bonding layer B1 and a plurality of bonding pads BP2 in the bonding layer B2 are connected to each other. Thereby, the control circuit provided in the control circuit layer 100 and the memory cell array 10 provided in the memory layer 200 are electrically connected to each other via the bonding pads BP1 and BP2. A region between the bonding layers B1 and B2 corresponds to a boundary portion between a layer formed using the semiconductor substrate W1 and a layer formed using the semiconductor substrate W2 (not shown).

### 1.1.5 Structure of Memory Cell Array

An example of the structure of the memory cell array 10 provided in the semiconductor memory device 3 according to the first embodiment will be described below. In the following description, an X direction corresponds to an extension direction of the word lines WL. A Y direction corresponds to an extension direction of the bit lines BL. The Z direction (first direction) is perpendicular to the X and Y directions. The Z direction is equivalent to the thickness direction of the semiconductor substrate W1. A plane extending in the X and Z directions is an XZ plane. A plane extending in the Y and Z directions is a YZ plane. Hatching is added appropriately in the plan view to improve the visibility of the drawing. Hatching added to the plan view is not necessarily related to the material or characteristics of a component to which the hatching is added. In the cross-sectional view, the illustration of the configuration is omitted appropriately to improve the visibility of the drawing.

### 1.1.5.1 Overview

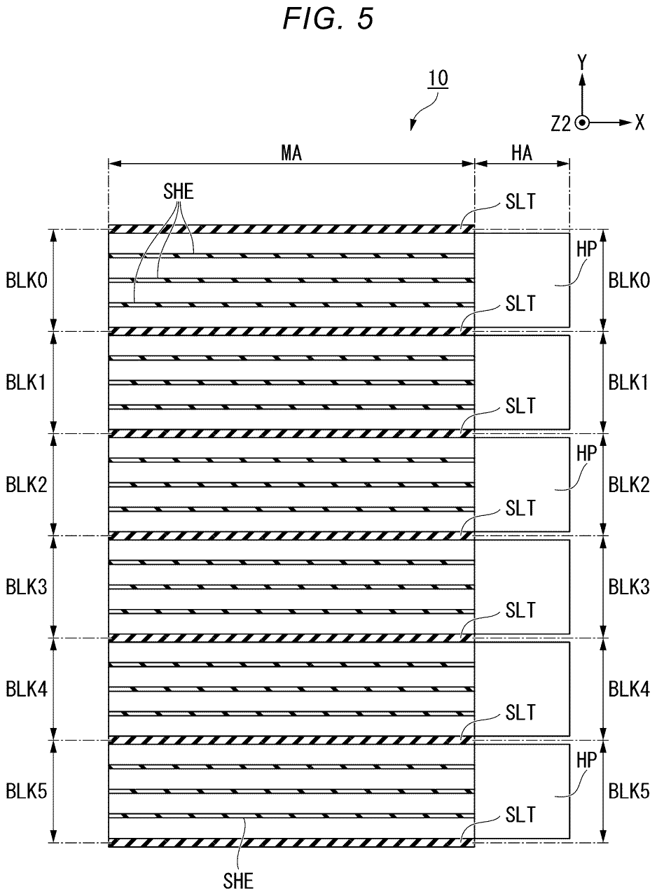

FIG. 5 is a plan view showing an example of a planar layout of the memory cell array provided in the semiconductor memory device according to the first embodiment. In FIG. 5, regions corresponding to six blocks BLK0 to BLK5 are shown. The serial numbers at the ends for distinguishing the blocks BLK are assigned in ascending order from the top of the paper. In the memory cell array 10, for example, the layout shown in FIG. 5 is repeatedly disposed in the Y direction. As shown in FIG. 5, the memory cell array 10 includes a plurality of members SLT and a plurality of members SHE. The planar layout of the memory cell array 10 is divided, for example, in the X direction into a memory area MA and a lead-out area HA. The lead-out area HA is provided adjacent to the memory area MA.

The lead-out area HA is an area used for connecting a stacked wiring, which is configured with a plurality of wiring layers (for example, the word lines WL0 to WLn and the select gate lines SGS0, SGS1, and SGD) stacked at a distance from each other in the Z direction, to the row decoder module 16.

The plurality of members SLT each extend in the X direction and are lined up in the Y direction. Each of the members SLT crosses the memory area MA in the X direction in a boundary region between adjacent blocks BLK. In other words, each of the regions separated by the members SLT corresponds to one block BLK in the memory cell array 10. Each of the members SLT has a structure in which, for example, an insulator and a plate-shaped contact are embedded. Each of the members SLT separates adjacent stacked wirings via the member SLT.

The plurality of members SHE are disposed in the memory area MA. The plurality of members SHE corresponding to the memory area MA are each provided across the memory area MA in the X direction and lined up in the Y direction. The end portions of the members SHE corresponding to the memory area MA are included in the lead-out area HA. For example, in the memory area MA, three members SHE are each disposed between the members SLT adjacent to each other in the Y direction. Each combination of regions separated by the members SLT and SHE in the memory area MA corresponds to one string unit STR in the memory cell array 10. For example, each of the members SHE has a structure in which an insulator is embedded. Each of the members SHE separates the select gate lines SGD adjacent to each other via the member SHE.

The planar layout of the memory cell array 10 of the semiconductor memory device 3 according to the first embodiment is not limited to the layout described above. For example, the number of members SHE disposed between adjacent members SLT can be designed to be any number. The number of string units STR formed between adjacent members SLT can be changed on the basis of the number of members SHE disposed between adjacent members SLT. The number of string units STR formed between adjacent members SLT is preferably an even number. That is, the number of members SHE in one block BLK is preferably an odd number.

The lead-out area HA includes a plurality of lead-out parts HP. In each of the lead-out parts HP, a connection part with a contact in each wiring layer of the stacked wiring is provided. The lead-out parts HP are lined up in the Y direction and each provided for each block BLK.

### 1.1.5.2 Memory Area

### Planar Layout

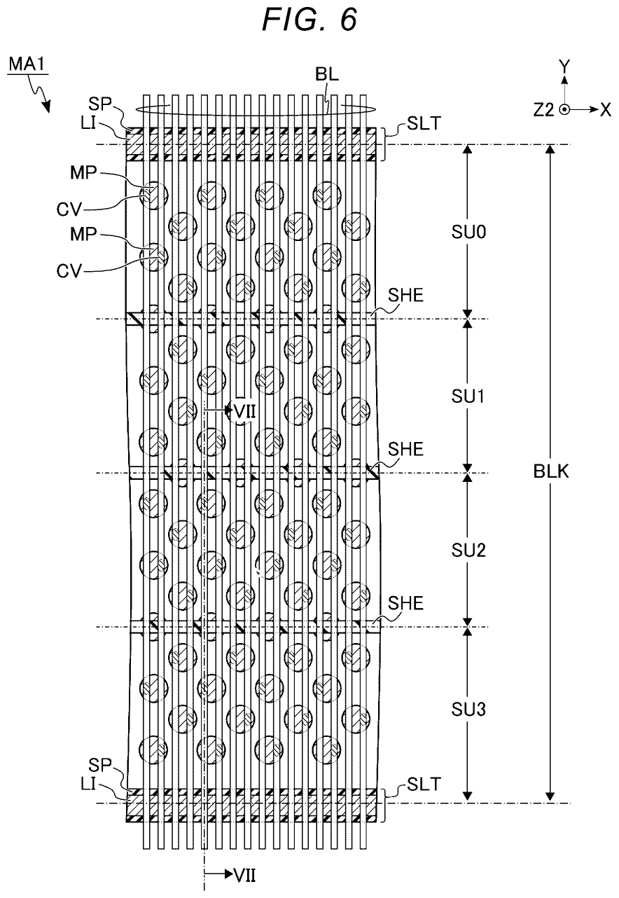

FIG. 6 is a plan view showing an example of a planar layout in the memory area of the memory cell array provided in the semiconductor memory device according to the first embodiment. FIG. 6 shows the structure of one block BLK in the memory area MA as a representative example. As shown in FIG. 6, in the memory area MA, the memory cell array 10 includes a plurality of columnar bodies (memory pillars) MP, a plurality of contacts CV, and a plurality of bit lines BL. In addition, each of the members SLT includes a contact LI and a spacer SP.

Each of the columnar bodies MP functions as, for example, one NAND string NS. The plurality of columnar bodies MP are disposed in a staggered pattern of, for example, 19 rows in the Y direction in a region between two adjacent members SLT. In the example shown in FIG. 6, counting from the top of the paper, one member SHE overlaps each of the columnar bodies MP in the 5th, 10th, and 15th rows.

The plurality of bit lines BL each extend in the Y direction and are lined up in the X direction. Each of the bit lines BL is disposed to overlap at least one columnar body MP for each string unit STR. In the example shown in FIG. 6, two bit lines BL are disposed to overlap one columnar body MP. When there are a plurality of bit lines BL overlapping the columnar body MP, one of the plurality of bit lines BL is electrically connected to one corresponding columnar body MP via a contact CV. When only one bit line BL overlaps the columnar body MP, the bit line BL is electrically connected to one corresponding columnar body MP via the contact CV.

For example, a contact CV between the columnar body MP in contact with the member SHE and the corresponding bit line BL is omitted. In other words, a contact CV between the columnar body MP and the bit line BL in contact with two different select gate lines SGD is omitted. The number and arrangement of the columnar bodies MP and the members SHE between adjacent members SLT are not limited to the configuration shown in FIG. 6, and can be changed as appropriate. For example, the number of bit lines BL overlapping each columnar body MP can be designed to be any number.

The contact LI is a conductor extending in the XZ plane. The lower surface of the contact LI is in contact with the source line SL (not shown). The spacer SP is an insulator provided on the side surface of the contact LI. In other words, the spacers SP are provided in contact with the contact LI so as to sandwich the contact LI in the Y direction.

### Cross-Sectional Structure

FIG. 7 is a cross-sectional view taken along line VII-VII in FIG. 6, showing an example of the cross-sectional structure in the memory area of the memory cell array of the semiconductor memory device according to the first embodiment. As shown in FIG. 7, the memory cell array 10 further includes wiring layers 21 to 25, insulator layers 40 to 46, and a member SSE. In the following description, the Z2 direction may be taken as the upward direction, and the Z1 direction may be taken as the downward direction.

The stacked wiring provided in the memory cell array 10 includes a wiring layer 22 corresponding to the select gate line SGS, a plurality of wiring layers 23 corresponding to the word lines WL0 to WLn, and a wiring layer 24 corresponding to the select gate line SGD.

In the example shown in FIG. 7, two wiring layers 22 corresponding to the select gate line SGS are provided.

In the following description, the select gate line SGS corresponding to the upper wiring layer 22 is referred to as a select gate line SGSa, and the select gate line SGS corresponding to the lower wiring layer 22 is referred to as the select gate line SGSb. Hereinafter, when the select gate lines SGSa and SGSb are not to be distinguished from each other, they are simply referred to as a select gate line SGS. The select gate lines SGSa and SGSb are connected to gates of select transistors ST2a and ST2b, respectively. The select transistors ST2a and ST2b function as one select transistor ST2. The number of wiring layers 22 corresponding to the select gate line SGS may be one or three or more. When the wiring layer 22 corresponding to the select gate line SGS is formed by a plurality of layers, the select transistors ST2a and ST2b may be configured to function independently.

An insulator layer 41 is stacked above the semiconductor substrate (not shown), and a plurality of wiring layers 22 and a plurality of insulator layers 42 are further stacked alternately above it. In the example shown in FIG. 7, two wiring layers 22 and two insulator layers 42 are stacked alternately. The plurality of wiring layers 22 are formed, for example, in a plate shape extending in the X direction on the XY plane. Each of the wiring layers 22 is used as the select gate line SGSa or SGSb. Each of the wiring layers 22 contains, for example, tungsten (W) or molybdenum (Mo). Each of the insulator layer 41 and the plurality of insulator layers 42 contains, for example, silicon oxide (SiO).

Above the uppermost insulator layer 42, a plurality of wiring layers 23 and a plurality of insulator layers 43 are stacked alternately. In the example shown in FIG. 7, n wiring layers 23 and (n-1) insulator layers 43 are stacked alternately. Each of the wiring layers 23 is formed, for example, in a plate shape extending in the X direction on the XY plane. Starting from the wiring layer 22 side, the wiring layers 23 are used as the word lines WL0 to WLn. Each of the wiring layers 23 contains, for example, tungsten. Each of the insulator layers 43 contains, for example, silicon oxide.

Above the uppermost wiring layer 23, an insulator layer 44, a wiring layer 24, and an insulator layer 45 are stacked in this order. The wiring layer 24 is formed, for example, in a plate shape extending in the X direction on the XY plane. The wiring layer 24 is used as the select gate line SGD. The wiring layer 24 contains, for example, tungsten. The insulator layers 44 and 45 contain, for example, silicon oxide.

Above the insulator layer 45, a wiring layer 25 is stacked. The wiring layer 25 is formed, for example, in a line shape extending in the Y direction. The wiring layer 25 is used as the bit line BL. In a region not shown in the drawing, a plurality of wiring layers 25 are lined up in the X direction. The wiring layer 25 contains, for example, copper.

Above the wiring layer 25, an insulator layer 46 is stacked. The insulator layer 46 is a layer that is connected to the bonding layer B2 and includes a plurality of wirings (not shown).

After the semiconductor substrate W2, which is not shown in FIGS. 3 and 4, is removed, the wiring layer 21 and the insulator layer 40 are provided in this order in the Z1 direction below the insulator layer 41. The wiring layer 21 is formed, for example, in a plate shape extending in the X direction on the XY plane. The wiring layer 21 is used as the source line SL. The wiring layer 21 contains, for example, silicon doped with phosphorus. Furthermore, the wiring layer 300 shown in FIG. 3 may be provided below the insulator layer 40. The wiring layer 300 includes a plurality of wirings (not shown).

Each of the columnar bodies MP is provided to extend in the Z direction (first direction). The columnar bodies MP penetrate the wiring layers 22 to 24 and the insulator layers 41 to 44.

In the example shown in FIG. 7, as an example, the stacked structure of the wiring layer 23 and the insulator layer 43 on a side close to the insulator layer 40 is referred to as a first stacked body 51. A three-layer structure is formed by stacking a second stacked body 52 and a third stacked body 53 above the first stacked body 51.

In the example shown in FIG. 7, a three-layer structure including the first to third stacked bodies 51 to 53 is illustrated as an example of a stacked structure including a plurality of stacked bodies. However, the number of stacked layers in the stacked body may be any number of layers, such as two layers or four or more layers.

The first stacked body 51 includes the insulator layers 41 and 42 and the wiring layer 22 stacked thereon, and further includes the wiring layer 22 and the insulator layer 43 repeatedly stacked above them.

The second stacked body 52 is stacked above the first stacked body 51, and has a structure in which the wiring layer 23 and the insulator layer 43 are repeatedly stacked.

The third stacked body 53 is stacked above the second stacked body 52, has a structure in which the wiring layer 23 and the insulator layer 43 are repeatedly stacked, and further includes the insulator layer 44 and the wiring layer 24.

In the example shown in FIG. 7, the stacked structure in which the wiring layer 23 and the insulator layer 43 are repeatedly stacked has a three-layer structure including the first stacked body 51, the second stacked body 52, and the third stacked body 53 with predetermined thicknesses from the insulator layer 42 side. In addition, the first stacked body 51 includes the first columnar body MP1 that penetrates the first stacked body 51 in the Z direction. The second stacked body 52 includes the second columnar body MP2 that penetrates the second stacked body 52 in the Z direction. The third stacked body 53 includes the third columnar body MP3 that penetrates the third stacked body 53 in the Z direction.

The first columnar body MP1, the second columnar body MP2, and the third columnar body MP3 are connected in series in this order in the Z direction and function as one columnar body (memory pillar) MP.

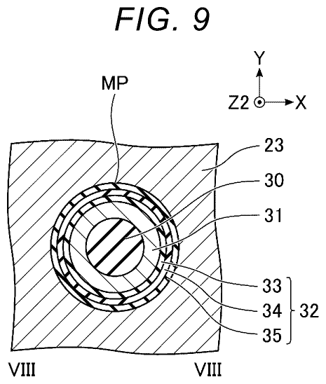

Each of the first to third columnar bodies MP1, MP2, and MP3 includes a core film 30, a semiconductor film 31, and a stacked film 32, as shown in FIG. 9, for example. In each of the columnar bodies MP, the core film 30 is provided to extend in the Z direction. For example, an upper end of the core film 30 of the third columnar body MP3 is located in the insulator layer 45, and a lower end of the core film 30 of the first columnar body MP1 is located in the wiring layer 21. The core film 30 includes an insulator such as silicon oxide. The semiconductor film 31 covers the periphery of the core film 30, for example. At a lower end of the first columnar body MP1, a part of the semiconductor film 31 is in contact with the wiring layer 21. The semiconductor film 31 contains silicon, for example. The stacked film 32 covers the side surface of the semiconductor film 31 except for a portion where the semiconductor film 31 is in contact with the wiring layer 21.

FIG. 9 shows an example of the cross section of the columnar body MP provided in the semiconductor memory device according to the first embodiment. More specifically, FIG. 9 shows a cross-sectional structure of the columnar body MP in a layer parallel to the surface of the semiconductor substrate (not shown) and including the wiring layer 23. As shown in FIG. 9, the stacked film 32 includes, for example, a tunnel insulating film 33, a charge storage film 34, and a block insulating film 35.

In the cross section including the wiring layer 23, the core film 30 is provided, for example, in the center of the columnar body MP. The semiconductor film 31 surrounds the side surface of the core film 30. The tunnel insulating film 33 surrounds the side surface of the semiconductor film 31. The charge storage film 34 surrounds the side surface of the tunnel insulating film 33. The block insulating film 35 surrounds the side surface of the charge storage film 34. The wiring layer 23 surrounds the side surface of the block insulating film 35.

In the columnar body MP, the core film 30, the semiconductor film 31, the tunnel insulating film 33, the charge storage film 34, and the block insulating film 35 are each continuous from one end of the columnar body MP in the Z direction to the other end.

The semiconductor film 31, the tunnel insulating film 33, the charge storage film 34, and the block insulating film 35 are formed to have a predetermined thickness in the XY direction (second direction) that intersects the Z direction (first direction). Thus, the block insulating film 35 is provided on the plurality of wiring layers 23 and the plurality of insulator layers 43 in the second direction. Similarly, the charge storage film 34 is provided on the block insulating film 35 in the second direction. The tunnel insulating film 33 is provided on the charge storage film 34 in the second direction. The semiconductor film 31 is provided on the tunnel insulating film 33 in the second direction.

The semiconductor film 31 is used as a channel (current path) for the memory cell transistors MT0 to MTn and the select transistors ST1 and ST2. The tunnel insulating film 33 and the block insulating film 35 each contain, for example, silicon oxide. The charge storage film 34 has a function of storing charges and contains, for example, silicon nitride (SiN). With this configuration, each columnar body MP can function as one NAND string NS.

Each of the first to third columnar bodies MP1, MP2, and MP3 include memory cells as non-volatile semiconductor memory devices. The memory cell is, for example, a charge trap type memory cell.

The core film 30 functions as a region in which a channel is formed.

The wiring layer 23 functions as a control gate of the memory cell.

The charge storage film 34 functions as a data storage layer that stores charges injected from the core film 30.

That is, the memory cell having a structure in which the control gate surrounds the periphery of the channel is formed at an intersection between the core film 30 and each wiring layer 23.

The block insulating film 35 is an insulating layer that prevents the charges stored in the charge storage film 34 from diffusing to the wiring layer 23. The block insulating film 35 is, for example, a silicon oxide layer.

The block insulating film 35 may have a multi-layer structure including a layer containing a material having a higher dielectric constant than silicon oxide. For example, silicon nitride can be used as the high dielectric constant material.

In the present embodiment, each of the first columnar body MP1, the second columnar body MP2, and the third columnar body MP3 has a cross-sectional area (XY cross-sectional area, cross-sectional area) along the XY plane which gradually increases upward from below. In other words, the inner diameter of a memory hole MH1 forming the first columnar body MP1 has a cross-sectional area (XY cross-sectional area: cross-sectional area) along the XY plane which gradually increases upward from below. That is, the memory hole MH1 has a portion where the inner diameter changes continuously upward from below.

The first columnar body MP1, the second columnar body MP2, and the third columnar body MP3, which are disposed to extend in the Z direction, are connected to each other and function as a single columnar body MP.

The first columnar body MP1 is formed in the first memory hole MH1 formed in the first stacked body 51. The second columnar body MP2 is formed in the second memory hole MH2 formed in the second stacked body 52. The third columnar body MP3 is formed in the third memory hole MH3 formed in the third stacked body 53.

Thus, an upper end of the first memory hole MH1 and a lower end of the second memory hole MH2 are connected to each other, and both the holes are continuous with each other. An upper end of the second memory hole MH2 and a lower end of the third memory hole MH3 are connected to each other, and both the holes are connected to each other.

A structure is obtained in which the first memory hole MH1 is formed in the first stacked body 51, and the first columnar body MP1 is accommodated in the first memory hole MH1. A structure is obtained in which the second memory hole MH2 is formed in the second stacked body 52, and the second columnar body MP2 is accommodated in the second memory hole MH2. A structure is obtained in which the third memory hole MH3 is formed in the third stacked body 53, and the third columnar body MP3 is accommodated in the third memory hole MH3.

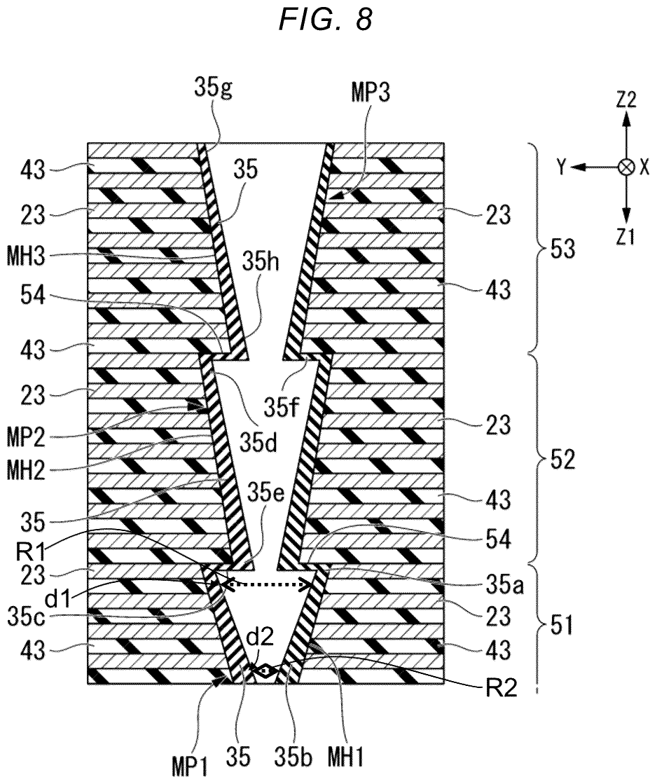

FIG. 8 shows a simplified relative relationship between the stacked bodies 51, 52, and 53 shown in FIG. 7 and the memory holes MH1, MH2, and MH3 that penetrate the stacked bodies in the Z direction. FIG. 8 also shows only the block insulating film 35 formed inside each of the memory holes MH1, MH2, and MH3. In FIG. 8, the scale in the Z direction is different from that in FIG. 7, and the lengths of the memory holes MH1, MH2, and MH3 in the Z direction are drawn to be reduced. Thus, in FIG. 8, a change in thickness of the block insulating film 35 in the Z direction is emphasized to the extent that it can be shown in FIG. 8.

As shown in FIG. 8,

That is, the film thickness of the block insulating film 35 in the first columnar body MP1 is inversely correlated with the size of the diameter of the first columnar body MP1. In other words, the film thickness of the block insulating film 35 in the first columnar body MP1 is inversely correlated with the size of the inner diameter of the first memory hole MH1. For example, if the hole inner diameters of the first memory hole MH1 at a first position and a second positions (the second position is lower than the first position) are R1 and R2 (R1>R2), respectively, the film thicknesses of the block insulating film 35 at the first and second positions are d1 and d2 (d1<d2), respectively. In other words, as the hole inner diameter of the first memory hole MH1 gradually decreases from R1 to R2, the film thickness of the block insulating film 35 gradually increases from d1 to d2.

For example, in the present embodiment, the film thickness of the block insulating film 35 at the lower end of the first columnar body MP1 is approximately 1 nm or more larger than the film thickness of the block insulating film 35 at the upper end of the first columnar body MP1. For example, in the present embodiment, the inner diameter of the first memory hole MH1 has a difference of 10 nm or more when comparing the inner diameter of the lower end (minimum inner diameter position) of the first memory hole MH1 with the inner diameter of the upper end (maximum inner diameter position) thereof. That is, there is a difference of 10 nm or more between the maximum inner diameter and the minimum inner diameter of the first memory hole MH1.

Since the upper end portion of the first memory hole MH1 has a larger diameter than the lower end portion of the second memory hole MH2, a peripheral step 54 is formed in the XY plane direction at the upper end portion of the first memory hole MH1. The film thickness of a protruding portion 35c of the block insulating film 35 formed along the inner surface of the peripheral step 54 is uniform. The protruding portion 35c connects the upper end of the block insulating film 35 of the first columnar body MP1 and the lower end of the block insulating film 35 of the second columnar body MP2. The film thickness of the protruding portion 35c in the block insulating film 35 is smaller than the film thickness of the upper end portion 35a in the block insulating film 35 on the first memory hole MH1 side. The film thickness of the upper end portion 35a in the block insulating film 35 is smaller than the film thickness of the lower end portion 35b of the block insulating film 35 on the first memory hole MH1 side.

For example, in the present embodiment, the inner diameter of the upper end of the first memory hole MH1 is 10 nm or more larger than the inner diameter of the lower end of the second memory hole MH2. For example, the film thickness of the block insulating film 35 located at the upper end of the first memory hole MH1 and the film thickness of the block insulating film 35 located at the lower end of the second memory hole MH2 have a thickness difference of 1 nm or more. For example, the film thickness of the block insulating film 35 located at the lower end of the second memory hole MH2 is larger than the film thickness of the block insulating film 35 located at the upper end of the first memory hole MH1.

The block insulating film 35 of the second columnar body MP2 is thinnest at an upper end portion 35d located at an upper end (an end in the Z2 direction) of the second columnar body MP2, gradually becomes thicker from the Z2 direction to the Z1 direction, and is thickest at a lower end portion 35e located at a lower end (an end in the Z1 direction) of the second columnar body MP2.

That is, the film thickness of the block insulating film 35 in the second columnar body MP2 is inversely correlated with the size of the diameter of the second columnar body MP2. In other words, the film thickness of the block insulating film 35 in the second columnar body MP2 is inversely correlated with the size of the inner diameter of the second memory hole MH2.

For example, in the present embodiment, the film thickness of the block insulating film 35 at the lower end of the second columnar body MP2 is approximately 1 nm or more larger than the film thickness of the block insulating film 35 at the upper end of the second columnar body MP2. For example, in the present embodiment, the inner diameter of the second memory hole MH2 has a difference of 10 nm or more when comparing the inner diameter of the lower end and the inner diameter of the upper end of the second memory hole MH2. That is, a difference between the maximum inner diameter and the minimum inner diameter of the second memory hole MH2 is 10 nm or more.

Since the upper end portion of the second memory hole MH2 has a larger diameter than the lower end portion of the third memory hole MH3, the peripheral step 54 is formed in the XY plane direction at the upper end portion of the second memory hole MH2. The film thickness of a protruding portion 35f of the block insulating film 35 formed along the inner surface of the peripheral step 54 is uniform. The protruding portion 35f connects the upper end of the block insulating film 35 of the second columnar body MP2 and the lower end of the block insulating film 35 of the third columnar body MP3. The film thickness of the protruding portion 35f in the block insulating film 35 is smaller than the film thickness of the upper end portion 35d of the block insulating film 35 on the second memory hole MH2 side.

The block insulating film 35 of the third columnar body MP3 is thinnest at an upper end portion 35g located at an upper end (an end in the Z2 direction) of the third columnar body MP3, gradually becomes thicker from the Z2 direction to the Z1 direction, and is thickest at a lower end portion 35h located at a lower end (an end in the Z1 direction) of the third columnar body MP3.

That is, the film thickness of the block insulating film 35 in the third columnar body MP3 is inversely correlated with the size of the diameter of the third columnar body MP3. In other words, the film thickness of the block insulating film 35 in the third columnar body MP3 is inversely correlated with the size of the inner diameter of the third memory hole MH3.

For example, in the present embodiment, the film thickness of the block insulating film 35 at the lower end of the third columnar body MP3 is approximately 1 nm or more larger than the film thickness of the block insulating film 35 at the upper end of the third columnar body MP3. For example, in the present embodiment, when comparing the inner diameter of the lower end of the third memory hole MH3 with the inner diameter of the upper end thereof, there is a difference of 10 nm or more therebetween. That is, there is a difference of 10 nm or more between the maximum inner diameter and the minimum inner diameter of the third memory hole MH3.

For example, in the present embodiment, the inner diameter of the upper end of the third memory hole MH3 is 10 nm or more larger than the inner diameter of the lower end of the third memory hole MH3. For example, there is a film thickness difference of 1 nm or more between the film thickness of the block insulating film 35 located at the upper end of the third memory hole MH3 and the film thickness of the block insulating film located at the lower end of the third memory hole MH3. For example, the film thickness of the block insulating film 35 located at the lower end of the third memory hole MH3 is larger than the film thickness of the block insulating film 35 located at the upper end of the third memory hole MH3.

The film thickness of the block insulating film 35 formed in each of the first columnar body MP1, the second columnar body MP2, and the third columnar body MP3 is described above. However, in each of the columnar bodies MP, the tunnel insulating film 33 and the charge storage film 34 may each have a similar film thickness relationship.

Alternatively, a combined film thickness of the block insulating film 35 and the tunnel insulating film 33 may have a similar film thickness relationship to the film thickness relationship described in the comparison between the block insulating films 35. A combined film thickness of the block insulating film 35 and the charge storage film 34 may have a similar film thickness relationship to the film thickness relationship described in the comparison between the block insulating films 35. A combined film thickness of the tunnel insulating film 33 and the charge storage film 34 may have a similar film thickness relationship to the film thickness relationship described in the comparison between the block insulating films 35. A combined film thickness of the block insulating film 35, the tunnel insulating film 33, and the charge storage film 34 may have a similar film thickness relationship to the film thickness relationship described in the comparison between the block insulating films 35.

For example, the tunnel insulating film 33 of the first columnar body MP1 is thinnest at an upper end portion located at an upper end (an end in the Z2 direction) of the first columnar body MP1, gradually becomes thicker from the Z2 direction to the Z1 direction, and is thickest at a lower end portion located at a lower end (an end in the Z1 direction) of the first columnar body MP1. The tunnel insulating film 33 formed in the second columnar body MP2 and the third columnar body MP3 also has a similar film thickness relationship.

For example, the charge storage film 34 of the first columnar body MP1 is thinnest at an upper end portion located at an upper end (an end in the Z2 direction) of the first columnar body MP1, gradually becomes thicker from the Z2 direction to the Z1 direction, and is thickest at a lower end portion located at a lower end (an end in the Z1 direction) of the first columnar body MP1. The charge storage film 34 formed in the second columnar body MP2 and the third columnar body MP3 also has a similar film thickness relationship.

Incidentally, a relationship between the first memory hole MH1, the second memory hole MH2, and the film thickness of the block insulating film 35 shown in FIGS. 7 and 8 can be expressed as a relationship to be described below.

The first memory hole (one memory hole) MH1 and the second memory hole (the other memory hole) MH2 are adjacent to each other in the Z direction (first direction). The first memory hole MH1 is located close to the semiconductor substrate W1, and the second memory hole MH2 is located far from the semiconductor substrate W1. At a connection position between the first memory hole MH1 and the second memory hole MH2, there is a portion where the inner diameters of the first memory hole MH1 and the second memory hole MH2 change discontinuously.

The block insulating film 35 having the above-mentioned film thickness relationship is formed in the first memory hole MH1 and the second memory hole MH2 having such a relationship.

In comparison between a position where the inner diameters of the memory holes MH1 and MH2 are small and a position where the inner diameters of the memory holes MH1 and MH2 are large, the block insulating film 35 has a larger film thickness at the position where the inner diameters of the memory holes MH1 and MH2 are small, and has a smaller film thickness at the position where the inner diameters of the memory holes MH1 and MH2 are large.

For example, at a connection position between the first memory hole MH1 and the second memory hole MH2, a difference between the maximum inner diameter of the first memory hole MH1 and the minimum inner diameter of the second memory hole MH2 can be 10 nm or more.

For example, a difference between the film thickness of the block insulating film 35 formed at the maximum inner diameter position of the first memory hole MH1 and the film thickness of the block insulating film 35 formed at the minimum inner diameter position of the second memory hole MH2 can be set to 1 nm or more.

For example, this relationship can be set in a similar manner in the relationship between the second memory hole MH2, the third memory hole MH3, and the film thickness of the block insulating film 35.

For example, this relationship is not only applied to the block insulating film 35, but may also be applied to at least one or two or more of the block insulating film 35, the charge storage film 34, and the tunnel insulating film 33 as described above.

In the columnar body MP shown in FIG. 7, a portion where the wiring layer 22 intersects the columnar body MP1 functions as the select transistor ST2. Portions where the columnar bodies MP1 to MP3 intersect the wiring layer 23 function as the memory cell transistors MT0 to MTn, respectively. A portion where the wiring layer 24 intersects the columnar body MP3 functions as the select transistor ST1.

A columnar contact CV is provided on the upper surface of the semiconductor film 31 in the columnar body MP. In the region shown in FIG. 7, two contacts CV are shown corresponding to two of the six columnar bodies MP. A different contact CV is connected in a region (not shown) to the columnar body MP that does not overlap the member SHE in the region and is not connected to the contact CV.

One wiring layer 25, that is, one bit line BL, is in contact with the upper surface of each contact CV. One wiring layer 25 is connected to one contact CV in each of spaces partitioned by the members SLT and SHE. In other words, each wiring layer 25 is electrically connected to, for example, one columnar body MP in each region between adjacent members SLT and SHE, and one columnar body MP in each region between two adjacent members SHE.

The member SLT is formed, for example, to extend along the XZ plane. Each of the members SLT penetrates the wiring layers 22 to 24 and the insulator layers 41 to 44. For example, the width of each of the members SLT in the Y direction increases upward from below.

In the member SLT, the contact LI is provided to extend along the XZ plane, and the spacer SP is provided between the contacts LI and the wiring layers 22 to 24 and the insulator layers 41 to 45. An upper end of the contact LI is located, for example, in the insulator layer 45. A lower end of the contact LI is in contact with, for example, the wiring layer 21. The contact LI may be omitted depending on the structure of the memory cell array 10.

The member SHE is formed, for example, in a plate shape extending along the XZ plane, and divides the wiring layer 24. An upper end of the member SHE is located in the insulator layer 45. A lower end of the member SHE is located, for example, in the uppermost insulator layer 43. The member SHE includes an insulating material such as silicon oxide. The upper end of the member SHE and the upper end of the member SLT may or may not be aligned. In addition, the upper end of the member SHE and the upper end of the columnar body MP may or may not be aligned.

The member SSE is formed in the memory areas MA1 and MA2, for example, in a plate shape extending along the XZ plane, and divides a plurality of wiring layers 22. For example, the upper end of the member SSE may be located at a boundary between the uppermost insulator layer 42 and the lowermost wiring layer 23, or may be located inside the uppermost insulator layer 42. For example, the lower end of the member SSE may be located at a boundary between the wiring layer 21 and the insulator layer 41, or may be located inside the insulator layer 41. It is preferable that the member SSE be provided at a position overlapping one member SHE in the Z direction in the memory areas MA1 and MA2. The member SSE includes an insulator such as silicon oxide. The lower end of the member SSE and the lower end of the member SLT may or may not be aligned.

### 1.2 Effects of First Embodiment

According to the first embodiment, the film thickness of the block insulating film 35 in the first columnar body MP1 is inversely correlated with the size of the diameter of the first columnar body MP1.

The degree of electric field concentration acting on the block insulating film 35 differs between a large diameter portion and a small diameter portion of the first columnar body MP1. The degree of electric field concentration is low in the large diameter portion of the first columnar body MP1, but is high in the small diameter portion. Thereby, the degree of electric field concentration acting on the block insulating film 35 differs between the large diameter portion and the small diameter portion of the first columnar body MP1. For example, writing is easy in a portion with a high degree of electric field concentration, and difficult in a portion with a low degree of electric field concentration.

In the structure according to the first embodiment, as clearly shown in FIG. 8, the block insulating film 35 is thick in a portion where the diameter of the first columnar body MP1 is small and the degree of electric field concentration is high, and the block insulating film 35 is thin in a portion where the diameter of the first columnar body MP1 is large and the degree of electric field concentration is low. By making the block insulating film 35 thicker, the electric field can be alleviated due to the presence of the thick block insulating film 35. For this reason, it is possible to slow down writing in a region where the diameter of the first columnar body MP1 is small and the degree of electric field concentration is high. Thereby, it is possible to align writing conditions in a region where the diameter of the first columnar body MP1 is large and the degree of electric field concentration is low. Thus, it is possible to solve a problem of data being written to a memory in a non-uniform manner depending on the size of the diameter of the first columnar body MP1. That is, it is possible to promote the uniformity of a write voltage in the memory cell array 10.

This effect is not limited to the first columnar body MP1, but can also be similarly obtained in the second columnar body MP2 and the third columnar body MP3, which have a structure similar to that of the first columnar body MP1.

Thus, it is possible to obtain similar effects in the entire memory cell array 10 provided with the columnar bodies MP.

When reading data from a memory, the data is read by applying a predetermined voltage lower than a write voltage in current semiconductor memory devices. In this case, even when a read voltage is lower than the write voltage, writing may occur slightly. When the degree of electric field concentration increases in a small diameter portion depending on the size of the diameter of the columnar body MP described above, there is a slight increase in the likelihood of writing.

On the other hand, in a structure provided with the first columnar body MP1, the second columnar body MP2, and the third columnar body MP3 described above, an electric field strength can be adjusted in accordance with the thickness of the block insulating film 35. For this reason, it is possible to reduce the problem of invalid writing which may occur slightly during reading.

In current semiconductor memory devices, it is implemented to form a stacked body configured with 100 or more layers of the wiring layers 23 and the insulator layers 43.

When forming memory holes MH in such a stacked body, there is a limit to the number of stacked layers that can be applied. For this reason, currently, a structure in which the first stacked body 51, the second stacked body 52, and the third stacked body 53 are stacked as shown in FIG. 7, or a structure in which more layers are stacked is adopted. The first memory hole MH1 is formed after forming the first stacked body 51, the second memory hole MH2 is formed after forming the second stacked body 52, and the third memory hole MH3 is formed after forming the third stacked body 53, resulting in a multi-layer structure.

When etching is performed on such a thick stacked structure to form the memory holes MH, holes having a smaller inner diameter at the bottom of the stacked body and a larger inner diameter at the top of the stacked body are inevitably formed from a difference in a processing time between the bottom side and the top side and the characteristics of an etching solution. Thus, the first to third columnar bodies MP1, MP2, and MP3 formed in the first to third stacked bodies 51, 52, and 53 also have cross-sectional shapes shown in FIG. 8.

Thus, when the structure according to the present embodiment is adopted, it is possible to promote the uniformity of the above-mentioned write voltage even in a multi-layer stacked structure.

In the above, an effect when the film thickness of the block insulating film 35 has an inverse correlation as described above was described so far. However, the above-mentioned inverse correlation may similarly be applied not only to the block insulating film 35 but also to the tunnel insulating film 33 and the charge storage film 34 in terms of their respective film thicknesses. By establishing the above-mentioned inverse correlation between the film thickness of the tunnel insulating film 33 and the film thickness of the charge storage film 34, similar effects as described above can be obtained.

Further, in the above, description was given of an example in which the present embodiment is applied to a stacked structure in which three stacked bodies are stacked, but the number of stacked layers of a stacked body may be two or four or more, and there is no limit to the number of stacked layers.

### 1.3 Block Insulating Film

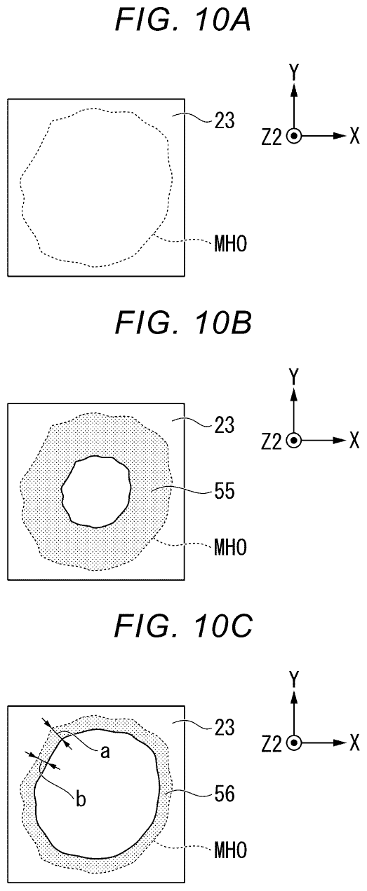

FIG. 10A shows an example of the shape of a memory hole MH0 formed in a part of a stacked body. The memory hole MH0 shown in FIG. 10A corresponds to memory hole MH shown in FIG. 9, and is shown as a cross-section of a portion penetrating the wiring layer 23.

A cross-sectional outline of the memory hole MH0 is not a shape similar to a circle, but has a shape with a variable radius of curvature. The memory hole MH0 with such a variable radius of curvature may be generated in a memory cell having a fine structure with an inner diameter of approximately several tens of nm.

When forming a block insulating film on the inner surface of the memory hole MH0, a thick film 55 formed of a material that configures the block insulating film is formed in advance as shown in FIG. 10B. The thick film 55 can then be slimmed to form a block insulating film 56 having a desired film thickness as shown in FIG. 10C.

In this case, the block insulating film 56 is formed such that a variation in the radius of curvature on the inner periphery side of a cross-sectional outline of the block insulating film 56 is smaller than a variation in the radius of curvature shown in the cross-sectional outline of the memory hole MH0 formed in the wiring layer 23 of the stacked body.

When the block insulating film 56 has a small variation in the radius of curvature on the inner periphery side in this manner, a preferable structure is obtained as described below. For example, a film thickness remains large at a point (a point shown by symbol a in FIG. 10C) where the radius of curvature of the outer periphery outline of the block insulating film 56 is small due to the slimming process. In addition, the film thickness becomes smaller (the variation in curvature becomes smaller) at a point (a point shown by symbol b in FIG. 10C) where the radius of curvature of the outer periphery outline of the block insulating film 56 is large. Thereby, it is possible to uniformize the way an electric field is applied to a channel (in the XY direction and the circumferential direction), resulting in a preferable structure.

The slimming process after forming a thick film can be applied not only to the block insulating film 56, but also to either the tunnel insulating film 33 or the charge storage film 34 applied in the structure according to the first embodiment.

For this reason, by applying the slimming process, it is possible to reduce a variation in curvature in either the tunnel insulating film 33 or the charge storage film 34 in the same manner as described above. As a result, it is possible to uniformize the way an electric field is applied to the channel.

Thus, by performing the slimming process after forming a thick film, it is possible to curb a variation in the radius of curvature on the inner periphery side in at least one of the tunnel insulating film 33, the charge storage film 34, and the block insulating film 56. Thus, it is possible to uniformize the way an electric field is applied to the channel.

### 2. Second Embodiment

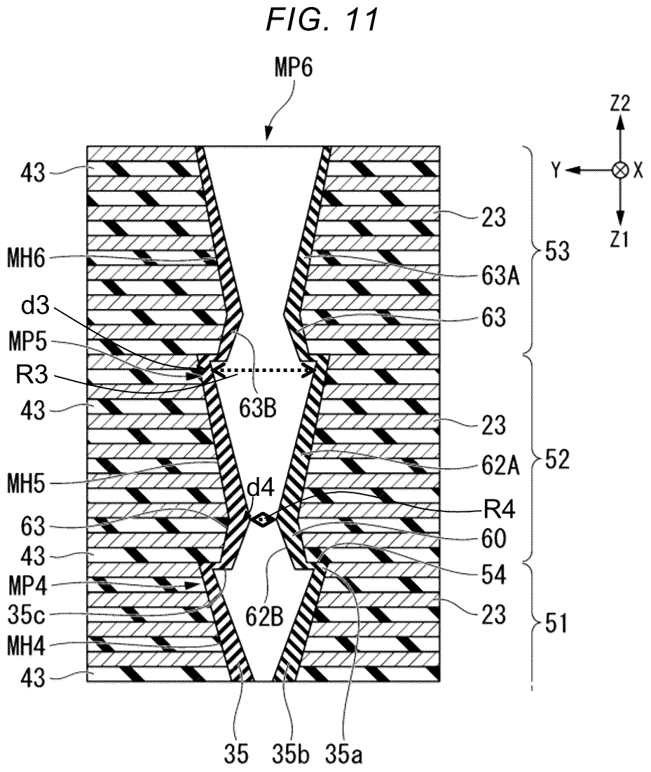

Next, a semiconductor memory device according to a second embodiment will be described with reference to FIG. 11.

In the semiconductor memory device according to the second embodiment, the shapes of the memory holes formed in the first stacked body 51, the second stacked body 52, and the third stacked body 53 according to the first embodiment are different, and the shapes of the columnar bodies formed in the respective memory holes are different.

Other structures are the same as those in the first embodiment, and thus the structures of memory holes and columnar bodies will be described below.

In the second embodiment, as shown in FIG. 11, a first memory hole MH4 is formed in a first stacked body 51 having the same structure as that in the first embodiment, a second memory hole MH5 is formed in a second stacked body 52, and a third memory hole MH6 is formed in a third stacked body 53. A structure in which a first columnar body is formed in the first memory hole MH4, a second columnar body is formed in the second memory hole MH5, and a third columnar body is formed in the third memory hole MH6 is also the same as in the first embodiment.

FIG. 11 corresponds to FIG. 8, and only a block insulating film formed in each memory hole is emphasized in a different scale. Also in the columnar body according to the second embodiment, a structure in which a block insulating film, a charge storage film, a tunnel insulating film, a semiconductor film, and a core film are stacked to form the columnar body is the same as in the first embodiment.

In the second embodiment, the shape of the first memory hole MH4 formed in the first stacked body 51 is the same as the shape of the first memory hole MH1 formed in the first stacked body 51 in the first embodiment. Thus, the shape of the block insulating film 35 formed along the inner surface of the first memory hole MH4 is the same as the shape of the block insulating film 35 in the first embodiment.

In the second embodiment, the cross-sectional area (XY cross-sectional area) and the inner diameter of the second memory hole MH5 along the XY plane gradually or continuously increase upward from below, from the upper side to the lower side of the second memory hole MH5. However, a connection part 60 is formed at the bottom of the second memory hole MH5, and the cross-sectional area (XY cross-sectional area) and the inner diameter of the connection part 60 along the XY plane gradually or continuously increase from the upper side to the lower side of the connection part 60.

Since the second memory hole MH5 has the shape described above, as shown in FIG. 11, if the hole inner diameters of the second memory hole MH5 at a first position and a second positions (the second position is lower than the first position) are R3 and R4 (R3>R4), respectively, the film thicknesses of the second block insulating film 62A at the first and second positions are d3 and d4 (d3<d4), respectively. In other words, as the hole inner diameter of the second memory hole MH5 gradually decreases from R3 to R4, the film thickness of the second block insulating film 62A gradually increases from d3 to d4. In addition, the film thickness of a bottom block insulating film 62B formed in the connection part 60 gradually becomes smaller as the bottom block insulating film 62B becomes closer to the first memory hole MH1. The film thickness of a bonding portion between the second block insulating film 62A and the bottom block insulating film 62B is the largest, the second block insulating film 62A is formed to gradually become thinner toward the upper side, and the bottom block insulating film 62B is formed to gradually become thinner toward the lower side.

In the second embodiment, the structure of the third memory hole MH6 is the same as that of the second memory hole MH5. That is, the film thickness of the third block insulating film 63A formed from the upper side to the lower side of the third memory hole MH6 gradually becomes larger from the upper side toward the lower side of the third memory hole MH6. In addition, the film thickness of the bottom block insulating film 62B formed in the connection part 63 gradually becomes smaller as the bottom block insulating film 62B becomes closer to the second memory hole MH5. The film thickness of a bonding portion between the third block insulating film 63A and the bottom block insulating film 63B is the largest, the third block insulating film 63A is formed to gradually become thinner toward the upper side, and the bottom block insulating film 63B is formed to gradually become thinner toward the lower side.

Also in the structure according to the second embodiment, the film thickness of the block insulating film 35 is generally inversely correlated with the size of the diameter of the first columnar body MP1.

As clearly shown in FIG. 11, the block insulating film 35 is made thicker in a portion where the diameter of the first columnar body MP1 is small and the degree of electric field concentration is high, and the block insulating film 35 is made thinner in a portion where the diameter of the first columnar body MP1 is large and the degree of electric field concentration is low.

For this reason, writing can be slowed down in a region where the diameter of the first columnar body MP1 is small and the degree of electric field concentration is high. Thereby, it is possible to align writing conditions in a region where the diameter of the first columnar body MP1 is large and the degree of electric field concentration is low. Thus, it is possible to solve a problem of data being written to a memory in a non-uniform manner depending on the size of the diameter of the first columnar body MP1.

This effect can also be similarly obtained in the second columnar body MP5, which has a structure similar to that of the first columnar body MP4, and in the third columnar body MP6, which has a structure similar to that of the first columnar body MP4.

Thus, also in the second embodiment, effects similar to those in the first embodiment can be obtained in the entire memory cell array 10 provided with the columnar bodies MP.

### 3. Third Embodiment

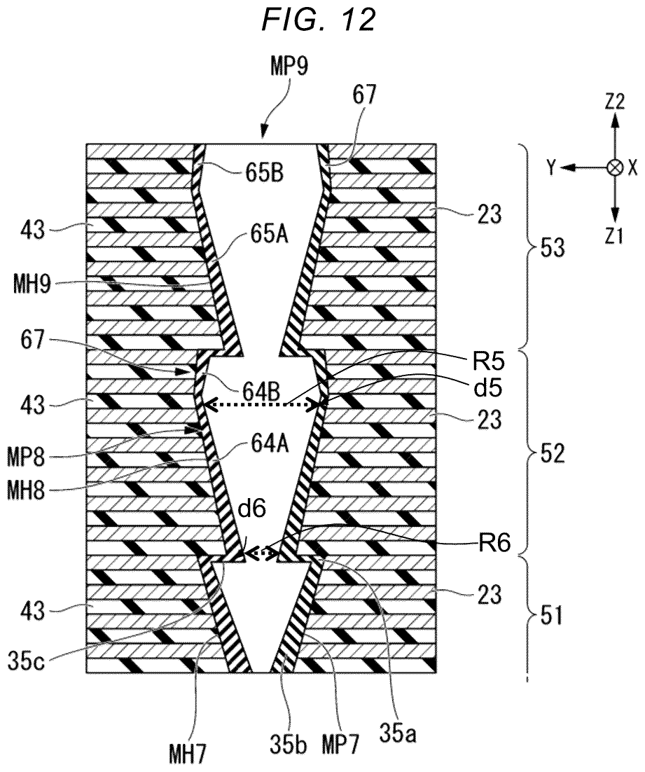

Next, a semiconductor memory device according to a third embodiment will be described with reference to FIG. 12.

In the semiconductor memory device according to the third embodiment, the shapes of the memory holes formed in the first stacked body 51, the second stacked body 52, and the third stacked body 53 according to the first embodiment are different, and the shapes of the columnar bodies formed in the respective memory holes are different.

Other structures are the same as those in the first embodiment, and thus the structures of memory holes and columnar bodies will be described below.

In the third embodiment, as shown in FIG. 12, a first memory hole MH7 is formed in a first stacked body 51 having the same structure as that in the first embodiment, a second memory hole MH8 is formed in a second stacked body 52, and a third memory hole MH9 is formed in a third stacked body 53. A structure in which a first columnar body is formed in the first memory hole MH7, a second columnar body is formed in the second memory hole MH8, and a third columnar body is formed in the third memory hole MH9 is also the same as in the first embodiment.

FIG. 12 corresponds to FIG. 8, and only a block insulating film formed in each memory hole is shown. Also in the columnar body according to the third embodiment, a structure in which a block insulating film, a charge storage film, a tunnel insulating film, a semiconductor film, and a core film are stacked to form the columnar body is the same as in the first embodiment.

In the third embodiment, the shape of the first memory hole MH7 formed in the first stacked body 51 is the same as the shape of the first memory hole MH1 formed in the first stacked body 51 in the first embodiment. Thus, the shape of the block insulating film 35 formed along the inner surface of the first memory hole MH7 is the same as the shape of the block insulating film 35 in the first embodiment.

In the third embodiment, as shown in FIG. 12, if the hole inner diameters of the second memory hole MH8 at a first position and a second positions (the second position is lower than the first position) are R5 and R6 (R5>R6), respectively, the film thicknesses of the block insulating film 64B at the first and second positions are d5 and d6 (d5<d6), respectively. In other words, as the hole inner diameter of the second memory hole MH8 gradually decreases from R5 to R6, the film thickness of the block insulating film 64B gradually increases from d5 to d6, and the cross-sectional area along the XY plane (The cross-sectional area along the XY plane (XY cross-sectional area) gradually decreases from the top to the bottom. However, a connection part 67 is formed at the top of the second memory hole MH8. The connection part 67 has a shape in which the cross-sectional area (XY cross-sectional area) along the XY plane gradually decreases upward from below.

The second memory hole MH8 has the shape described above. Due to this relationship, the film thickness of a second block insulating film 64A formed from the bottom to near the top of the second memory hole MH8 gradually becomes smaller toward the top from the bottom of the second memory hole MH8. In addition, the film thickness of a top block insulating film 64B formed at the connection part 67 gradually becomes larger as the top block insulating film 64B becomes closer to the third memory hole MH9. The film thickness of a bonding portion between the second block insulating film 64A and the top block insulating film 64B is the smallest, and the top block insulating film 64B is formed to gradually become thicker upward.

In the third embodiment, the cross-sectional area (XY cross-sectional area) of the third memory hole MH9 along the XY plane gradually increases upward from below, from the bottom to near the top. However, a connection part 67 is formed at the top of the third memory hole MH9, and the connection part 67 has a shape in which the cross-sectional area (XY cross-sectional area) of the connection part 67 along the XY plane gradually decreases toward the upper side from the lower side of the connection part 67.

The third memory hole MH9 has the shape described above. Due to this relationship, the film thickness of a third block insulating film 65A formed from the bottom to near the top of the third memory hole MH9 gradually becomes smaller toward the top from the bottom of the third memory hole MH9. In addition, the film thickness of a top block insulating film 65B formed at the connection part 67 gradually becomes larger as the top block insulating film 65B becomes closer to an upper end. The film thickness of a bonding portion between the third block insulating film 65A and the top block insulating film 65B is the smallest, and the top block insulating film 65B is formed to gradually become thicker upward.

Also in the structure according to the third embodiment, the film thickness of the block insulating film 35 is generally inversely correlated with the size of the inner diameter of the memory hole MH7 in the same manner as in the first and second embodiments.

As can be assumed from FIG. 12, the block insulating film 35 is made thicker in a portion where the diameter of the first columnar body MP7 is small and the degree of electric field concentration is high, and the block insulating film 35 is made thinner in a portion where the diameter of the first columnar body MP is large and the degree of electric field concentration is low.

For this reason, writing can be slowed down in a region where the inner diameter of the first memory hole MH7 is small and the degree of electric field concentration is high. Thereby, it is possible to align writing conditions in a region where the diameter of the first memory hole MH7 is large and the degree of electric field concentration is low. Thus, it is possible to solve a problem of data being written to a memory in a non-uniform manner depending on the size of the diameter of the first columnar body.

This effect can also be similarly obtained in the second columnar body MP8, which shows an inverse correlation with the size of the inner diameter of the second memory hole MH8. The above-mentioned effect can also be similarly obtained in the third columnar body MP9, which shows an inverse correlation with the size of the inner diameter of the third memory hole MH9.

Thus, effects similar to those in the first embodiment can be obtained in the entire memory cell array 10 provided with the columnar bodies MP having the structure shown in FIG. 12.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first stacked body in which a plurality of first wiring layers and a plurality of first insulator layers are alternately stacked along a first direction and a first hole is formed having a portion extending in the first direction and having an inner diameter changing along the first direction; and
a first columnar body extending within the first hole in the first direction and comprising:
a first semiconductor film positioned inside the first hole;
a first tunnel insulating film provided outside the first semiconductor film;
a first charge storage film located outside the first tunnel insulating film; and
a first block insulating film interposed between the first charge storage film and the plurality of first wiring layers and the plurality of first insulating layers;
In the second direction, at least one or more of the first block insulating film, the first charge storage film, and the first tunnel insulating film has a film thickness,
The first film thickness when the inner diameter of the first hole is the first inner diameter,
When the inner diameter of the first hole is the second inner diameter, the second film thickness, when the first inner diameter is larger than the second inner diameter, the first film thickness is smaller than the second film thickness.

2. The semiconductor device according to claim 1, wherein
a difference between the first inner diameter and the second inner diameter of the hole are 10 nm or more, and
a difference between the first film thickness and the second film thickness are 1 nm or more.

3. The semiconductor device according to claim 1, wherein the first film thickness and the second film thickness are the film thickness of the first block insulating film.

4. The semiconductor device according to claim 1, wherein
the first film thickness and the second film thickness are the film thickness of the first tunnel insulating film.

5. The semiconductor device according to claim 1, wherein the first film thickness and the second film thickness are the film thickness of the first charge storage film.

6. The semiconductor device according to claim 1, wherein the first semiconductor film, the first tunnel insulating film, the first charge storage film and the first tunnel insulating film are continuously formed from one end in the first direction to the other end in the first direction of the first stacked body.

7. The semiconductor device according to claim 1, wherein
the semiconductor device has variations including
a variation in a radius of curvature on an inner periphery side of a cross-sectional outline of the block insulating film,
a variation in a radius of curvature on an inner periphery side of a cross-sectional outline of the charge storage film, and
a variation in a radius of curvature on an inner periphery side of a cross-sectional outline of the tunnel insulating film, and
at least one of the variations is smaller than a variation in a radius of curvature of a cross-sectional outline of the first hole.

8. The semiconductor device according to claim 1, wherein
in the first stacked bodies, the inner diameter of the hole gradually becomes larger from one end side of the first portion in the first direction close to the other end side of the first direction, and the thickness of the first block insulating film is gradually reduced.

9. The semiconductor device according to claim 1, wherein
a second stacked bodies are formed above the first stacked bodies in the first direction,
a second stacked body in which a plurality of second wiring layers and a plurality of second insulator layers are alternately stacked along the first direction and a second hole is formed having a portion extending in the first direction and having an inner diameter changing along the first direction; and
a second columnar body extending within the second hole in the first direction and comprising:
a second semiconductor film positioned inside the second hole;
a second tunnel insulating film provided outside the second semiconductor film;
a second charge storage film located outside the second tunnel insulating film; and
a second block insulating film interposed between the second charge storage film and the plurality of second wiring layers and the plurality of second insulating layers;
the inner diameter of the upper end of the first hole is larger than the inner diameter of the lower end of the second hole.

10. The semiconductor device according to claim 9, wherein
In the second direction, when the thickness of at least one or more of the second block insulating film, the second charge storage film, and the second tunnel insulating film is set as the third film thickness when the inner diameter of the second hole is the third inner diameter and the fourth film thickness when the inner diameter of the second hole is the fourth inner diameter, when the third inner diameter is larger than the fourth inner diameter, the third film thickness is smaller than the fourth film thickness.

11. The semiconductor device according to claim 10, wherein
the third and fourth film thicknesses are the thicknesses of the second block insulating film.

12. The semiconductor device according to claim 10, wherein
the third and fourth film thicknesses are the thicknesses of the second tunnel insulating film.

13. The semiconductor device according to claim 10, wherein
the third and fourth film thicknesses are the thicknesses of the second charge storage film.

14. The semiconductor device according to claim 9, wherein
the second hole has a portion whose inner diameter increases and a portion whose inner diameter decreases from the bottom end to the top end of the second hole.

15. The semiconductor device according to claim 9, wherein
the inner diameter of the upper end of the first hole is at least 10 nm larger than the inner diameter of the lower end of the second hole.

16. The semiconductor device according to claim 9, wherein
The thickness of the block insulating film at the lower end of the second hole is 1 nm or more larger than the thickness at the upper end of the first hole.

17. The semiconductor device according to claim 9, wherein having an overhang at the upper end of the first columnar body.

18. The semiconductor device according to claim 17, wherein the overhang connects the upper end of the first block insulating film of the first columnar body to the lower end of the second block insulating film of the second columnar body.

19. The semiconductor device according to claim 9, wherein in the first direction, the source lines are formed below the first columnar and the bit lines are formed above the second columnar.
